(19) United States
(12) Patent Application Publication
(10) Pub. No.: US 2026/0344359 A1
(43) Pub. Date: Oct. 29, 2026

(54) APPARATUS AND METHOD FOR WAFER-TO-WAFER BONDING

(71) Applicant: Tokyo Electron Limited, Tokyo (JP)

(72) Inventors: Andrew Tuchman, Albany, NY (US); Nathan Ip, Austin, TX (US); Christopher Michael Netzband, Albany, NY (US); Ilseok Son, Albany, NY (US); Angelique Raley, Albany, NY (US); Arkalgud Sitaram, Albany, NY (US)

(21) Appl. No.: 19/190,212

(22) Filed: Apr. 25, 2025

(51) Int. Cl. H10P 72/76; H10W 72/00; H10W 80/00

(52) U.S. Cl. CPC H10P 72/7616; H10W 72/071; H10W 80/312; H10W 80/327

(57) ABSTRACT

An apparatus is provided for wafer bonding. The apparatus includes a flexible wafer chuck configured to support a first wafer. The apparatus further includes a pressure chamber within the flexible wafer chuck. A wall of the flexible wafer chuck separates the pressure chamber from the first wafer. The wall is configured to be anisotropically deformed when pressure is applied to the pressure chamber.

### TECHNICAL FIELD

The present invention relates generally to an apparatus and method for semiconductor manufacturing, and, in particular embodiments, to an apparatus and method for wafer-to-wafer bonding.

### BACKGROUND

Wafer-to-wafer (W2W) bonding process in semiconductor manufacturing is used to integrate complete wafers with one another to form a unified structure. A wafer refers to a thin slice of semiconductor material that serves as the substrate for microelectronic devices. W2W bonding enables the combination of diverse semiconductor technologies within a single platform, essential for creating advanced three-dimensional integrated circuits and system-in-package applications. Wafer-to-wafer bonding supports the development of heterogeneous integrations, where different types of wafers with different functionalities are combined to enhance device performance and efficiency. This process is widely applied in fabricating high-density electronic packages, including memory stacks, image sensors, and various miniaturized devices, meeting the growing demand for compact and powerful electronic solutions with increased functionality per unit volume.

### SUMMARY

In accordance with one aspect of the present invention, an apparatus for wafer bonding is provided. The apparatus includes a flexible wafer chuck configured to support a first wafer, a pressure chamber within the flexible wafer chuck, and a wall of the flexible wafer chuck separating the pressure chamber from the first wafer. The wall is configured to be anisotropically deformed when pressure is applied to the pressure chamber.

In accordance with another aspect of the present invention, an apparatus for wafer bonding is provided. The apparatus includes a flexible wafer chuck configured to hold a first wafer, a plurality of pressure chambers within the flexible wafer chuck, and a plurality of gas flow lines, each gas flow line coupled to each of the plurality of pressure chambers. The apparatus further includes a controller coupled to the plurality of gas flow lines, the controller configured to independently control gas flow into each of the plurality of pressure chambers and independently regulate pressure within each of the plurality of pressure chambers to anisotropically deform the flexible wafer chuck to compensate for anisotropic mechanical properties of the first wafer.

In accordance with yet another aspect of the present invention, a method for wafer bonding is provided. The method includes placing a first wafer over a flexible wafer chuck, the flexible wafer chuck comprising a pressure chamber, wherein a wall of the flexible wafer chuck separates the pressure chamber from the first wafer. The method further includes flowing a gas into the pressure chamber to apply a pressure to the wall of the pressure chamber to anisotropically deform the first wafer to compensate for anisotropic mechanical properties of the first wafer. The method also includes placing a second wafer on the first wafer, and bonding the second wafer to the first wafer.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1A-1D illustrate various views of a wafer bonding apparatus with custom flexible wafer chuck, in accordance with an embodiment;

FIGS. 2A-2D illustrate cross-sectional views of a method for wafer bonding using the wafer bonding apparatus, in accordance with an embodiment;

FIGS. 3A-3D illustrate cross-sectional views showing anisotropic deformation of the wafer during the bonding process illustrated in FIGS. 2A-2D, in accordance with an embodiment;

FIGS. 4A-4B illustrate an alternative embodiment featuring a plurality of pressure chambers in a wafer bonding apparatus, in accordance with an embodiment;

FIGS. 5A-5C illustrate wafer scaling due to anisotropic mechanical properties in different silicon crystal orientations, in accordance with an embodiment;

FIGS. 6A-6C illustrate height maps of custom wafer flexible chuck for compensating anisotropic scaling, in accordance with an embodiment;

FIG. 7 illustrates performance data demonstrating reduced residual misalignment using custom flexible wafer chuck, in accordance with an embodiment;

FIG. 8 illustrates cumulative probability distributions showing improved wafer alignment using custom flexible wafer chuck, in accordance with an embodiment; and

FIG. 9 illustrates a process flow diagram for wafer bonding using the custom flexible wafer chuck, in accordance with an embodiment.

### DETAILED DESCRIPTION OF ILLUSTRATIVE EMBODIMENTS

During wafer-to-wafer (W2W) bonding (or referred to as wafer bonding) processes, a top wafer stretches during bond propagation, leading to radially increasing misalignment that can reach up to 1 micrometer at the wafer edge. This misalignment creates challenges for achieving precise connections between the wafers, particularly as semiconductor feature sizes continue to shrink. In conventional approaches, a flexible or expandable wafer chuck is used to stretch a bottom wafer before bonding to compensate for this scaling error. The conventional wafer chuck may deform into a dome shape when pressurized, creating an in-plane distortion of the bottom wafer that aims to match the stretching of the top wafer.

However, silicon wafers may exhibit mechanical anisotropy, where the elasticity may vary depending on the direction within the wafer plane. For example, a (100) silicon wafer may stretch more along the X and Y directions than along diagonal directions. This anisotropic behavior creates direction-dependent scaling patterns that cannot be adequately corrected by conventional flexible wafer chuck designs, which provide only isotropic deformation. The residual misalignment resulting from this uncompensated anisotropy may impact device yield and performance.

In various embodiments, a custom flexible wafer chuck may be utilized to address these direction-dependent misalignment issues. The custom flexible wafer chuck may include a pressure chamber with a wall separating from the bottom wafer. The wall may have thickness or materials composition variations that depend on both radial and angular positions. When the pressure chamber is pressurized, the wall may have different local deformation responses due to thickness or materials composition variations, which may anisotropically deform the bottom wafer to accommodate the anisotropic mechanical properties of silicon. In one or more embodiments, the flexible chuck may be customized for different silicon crystal orientations, such as (111), (100), or (110) with different mechanical anisotropy properties.

In one or more embodiments, the custom flexible wafer chuck may utilize different materials, pressure distributions, or combinations thereof to achieve the desired anisotropic deformation. In an embodiment, the custom flexible wafer chuck may include multiple independently controlled pressure chambers to provide more precise control over the anisotropic deformation. The anisotropic deformation capability of the custom flexible wafer chuck can be particularly beneficial for advanced semiconductor nodes where alignment requirements are increasingly stringent.

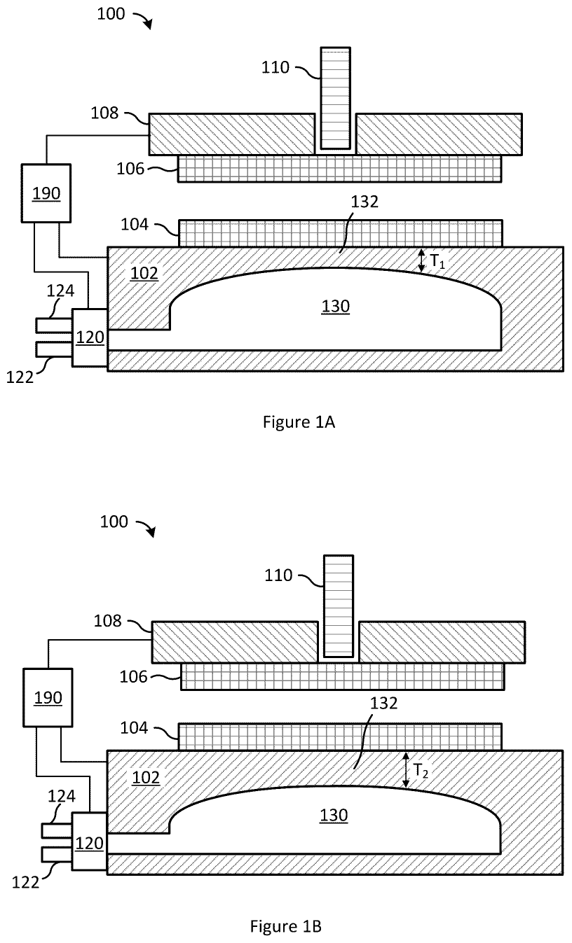

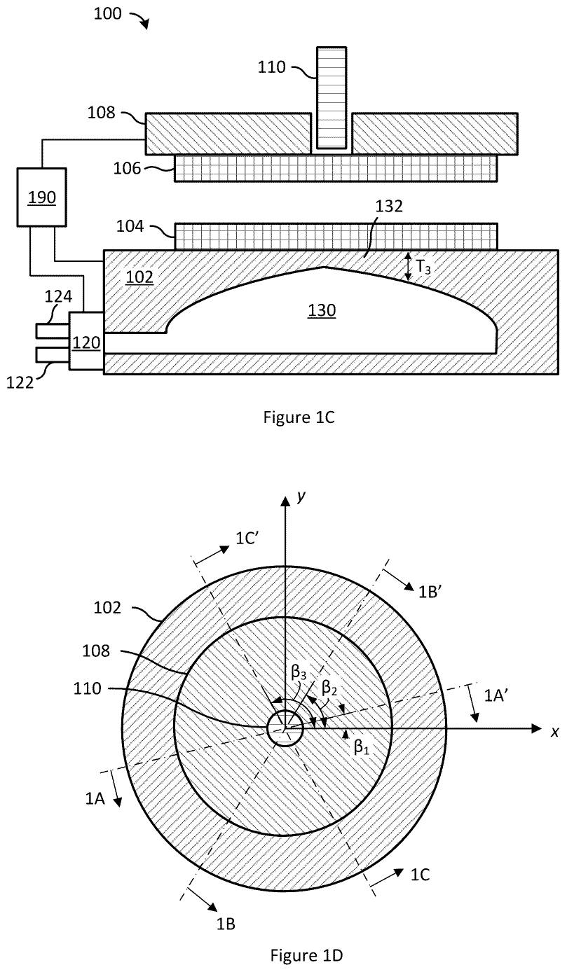

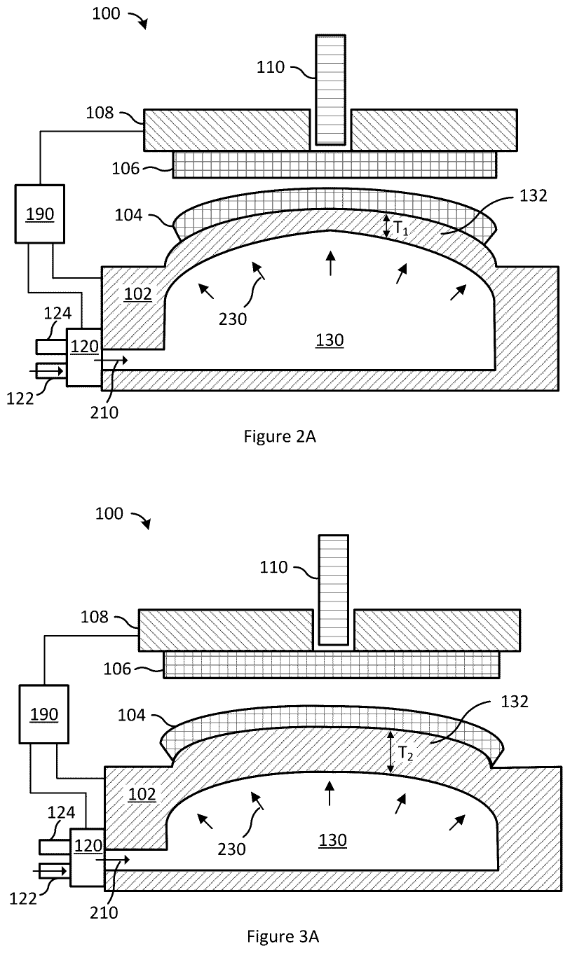

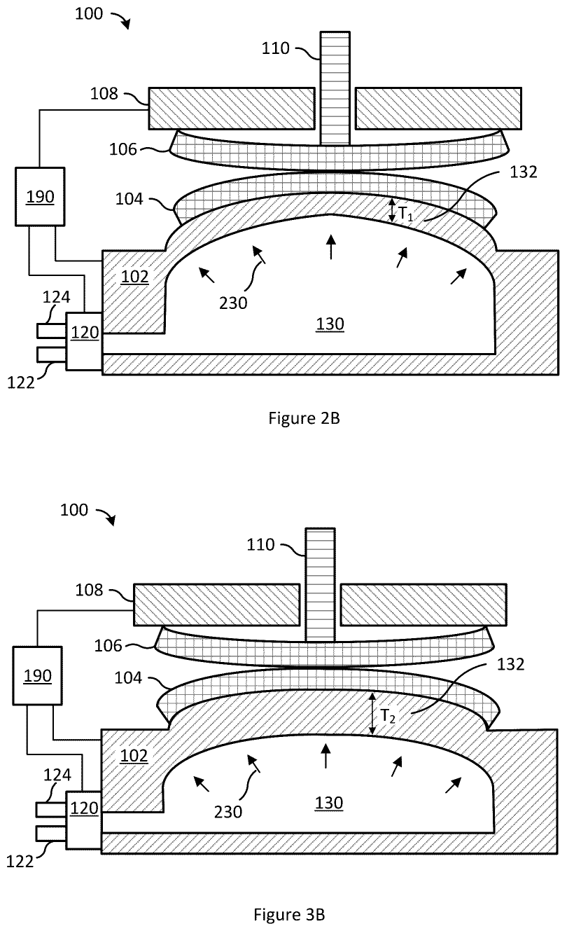

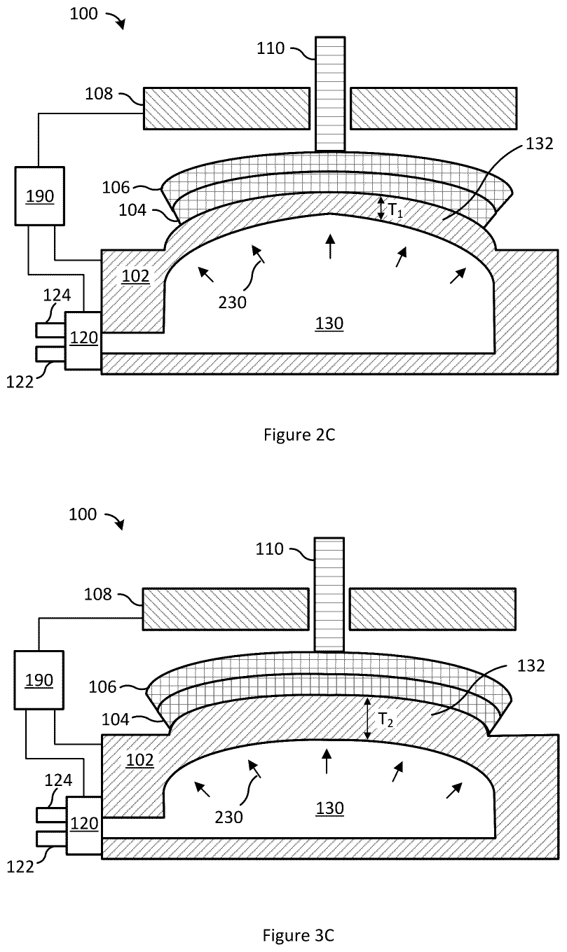

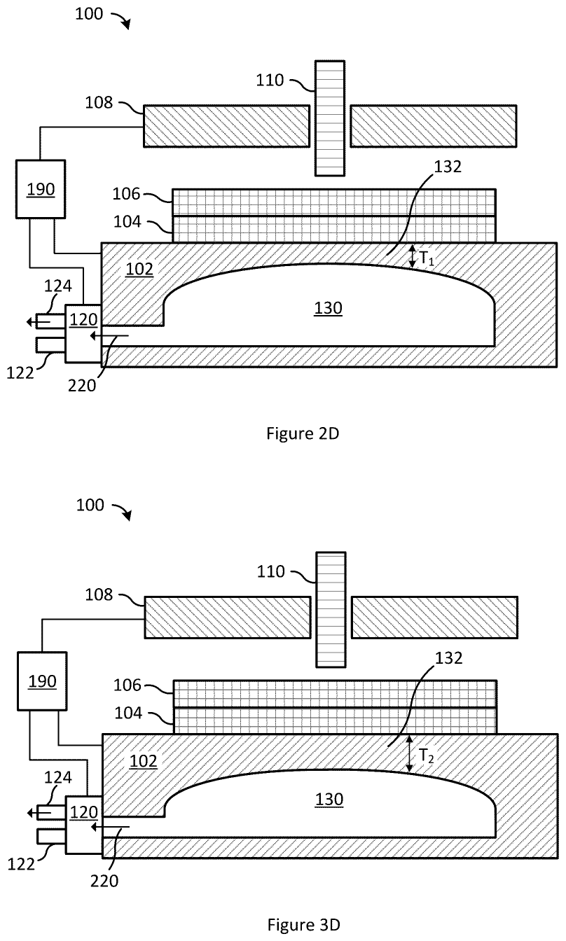

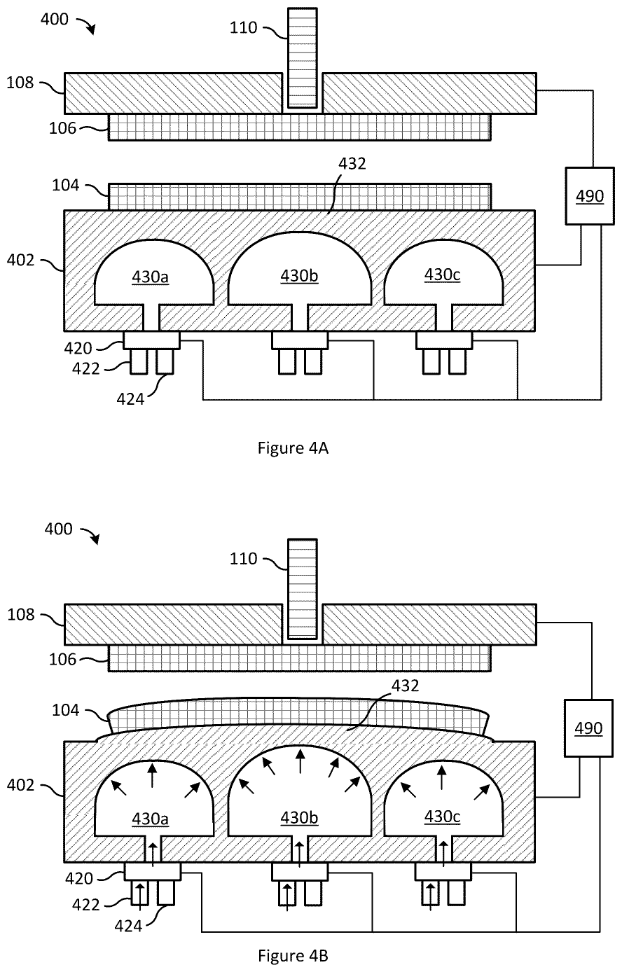

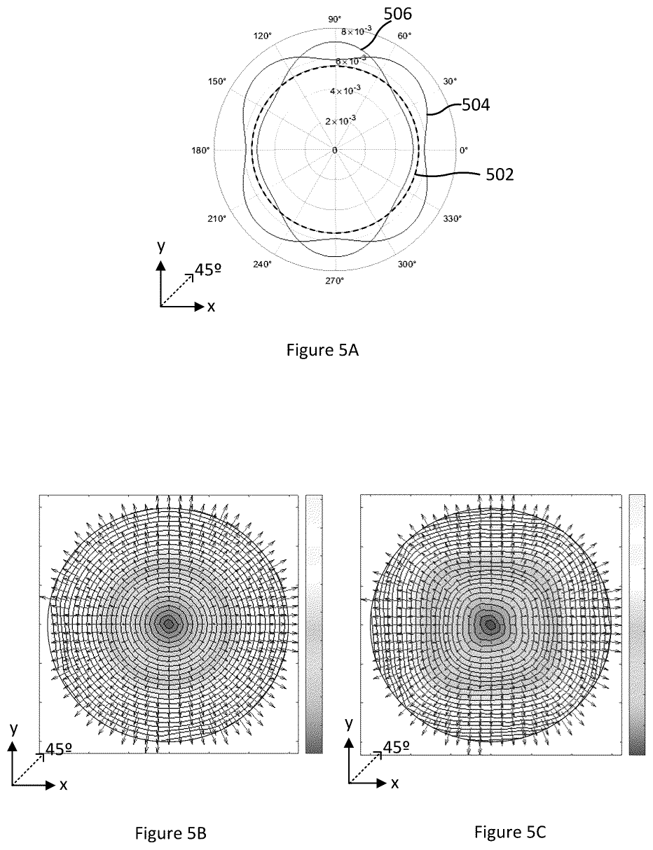

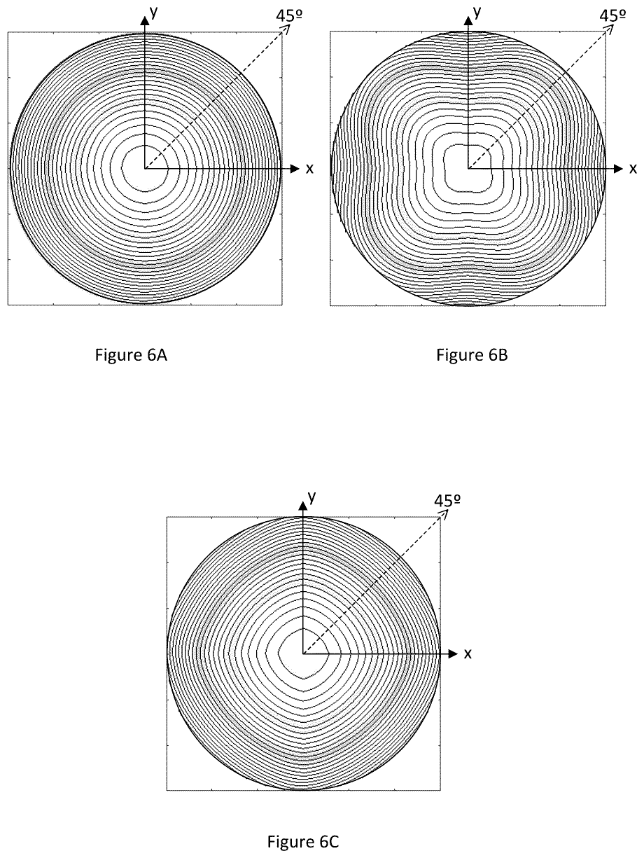

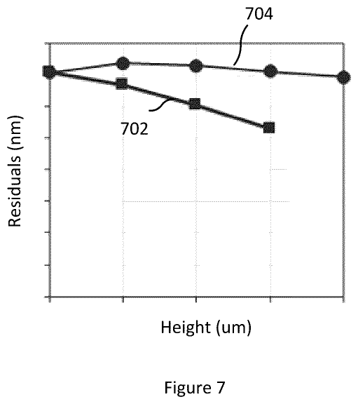

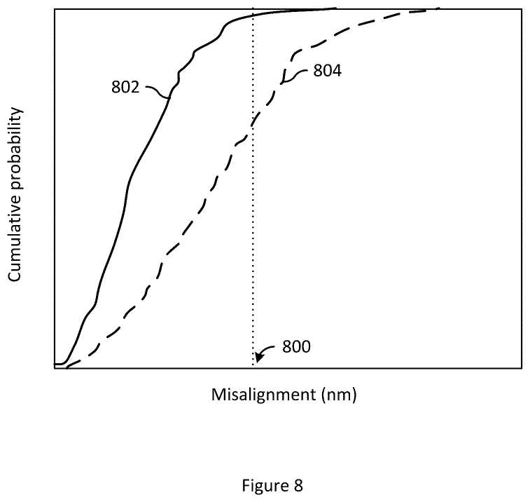

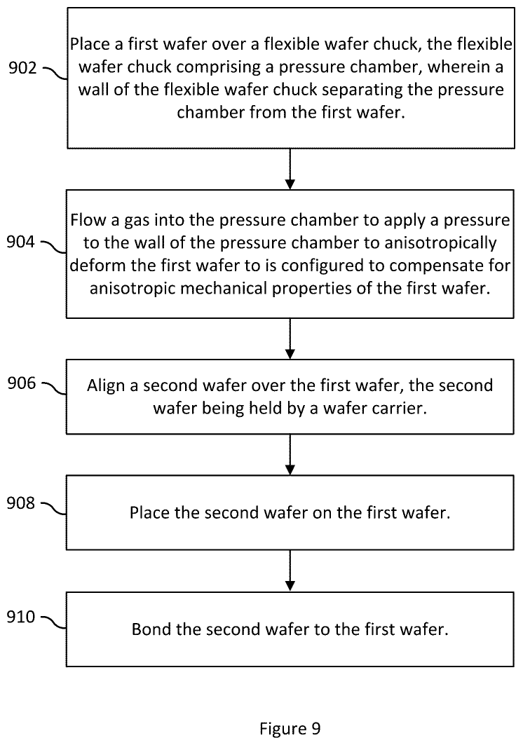

Embodiments of the disclosure are described in the context of the accompanying drawings. An embodiment of a wafer bonding apparatus 100 with custom flexible wafer chuck thickness variations is illustrated in FIGS. 1A-1D. The method of wafer bonding using the wafer bonding apparatus along cross-section 1A-1A′ is described in FIGS. 2A-2D. The anisotropic deformation of the wafer during the bonding process along cross-section 1B-1B′ is illustrated in FIGS. 3A-3D. An alternative embodiment featuring a plurality of pressure chambers in a wafer bonding apparatus is shown in FIGS. 4A-4B. The anisotropic scaling due to anisotropic mechanical properties in different silicon crystal orientations are illustrated in FIGS. 5A-5C. Height maps of custom wafer flexible chuck for compensating anisotropic scaling is presented in FIGS. 6A-6C. Performance data demonstrating reduced residual misalignment using the custom flexible wafer chuck is shown in FIG. 7. Cumulative probability distributions showing improved product quality through reduced misalignment are illustrated in FIG. 8. A process flow diagram for wafer bonding using the custom flexible wafer chuck is presented in FIG. 9.

FIGS. 1A-1D illustrate a wafer bonding apparatus 100 with a custom flexible wafer chuck, in accordance with an embodiment. A custom flexible wafer chuck may also be referred to below as a flexible wafer chuck. FIGS. 1A, 1B, and 1C represent cross-sectional views of the wafer bonding apparatus 100 along lines 1A-1A′, 1B-1B′, and 1C-1C′ in FIG. 1D, respectively, where FIG. 1D illustrates a top view of the wafer bonding apparatus 100. The cross-sectional views of the wafer bonding apparatus 100 along lines 1A-1A′, 1B-1B′, and 1C-1C′ may also be referred to below as cross-sections 1A-1A′, 1B-1B′, and 1C-1C′, respectively.

The wafer bonding apparatus 100 may comprise a flexible wafer chuck 102 (or referred to as a custom flexible wafer chuck 102) configured to support a first wafer 104. In various embodiments, the first wafer 104 may be a blank silicon wafer, a silicon-on-insulator (SOI) wafer, a gallium arsenide wafer, a silicon carbide wafer, a quartz wafer, or any of various other semiconductor wafers. The first wafer 104 may also be coated or layered with any number of additional materials, including compound semiconductors, metals, metal oxides, or metal nitrides.

The flexible wafer chuck 102 may provide both structural support for the first wafer 104 and anisotropic deformation capability necessary for precise wafer alignment. In various embodiments, the flexible wafer chuck 102 may be fabricated from ceramic or polymer materials that exhibit appropriate flexibility, durability, and chemical resistance. In one or more embodiments, materials of the flexible wafer chuck 102 may comprise polyimide, polydimethylsiloxane (PDMS), polyether ether ketone (PEEK), fluoropolymers, polyurethane, silicone elastomers, or fluoroelastomers. In some embodiments, the flexible wafer chuck 102 may comprise ceramic materials such as silicon carbide, silicon nitride, aluminum oxide, aluminum nitride, zirconium oxide, or the combination thereof. The selection of material may depend on specific application requirements, including temperature range, chemical compatibility, and mechanical properties.

In various embodiments, the flexible wafer chuck 102 may comprise a flat upper surface with vacuum channels (not shown) that create suction to hold the first wafer 104 firmly in position. These vacuum channels may be arranged in concentric circles or other patterns to ensure uniform holding force across the wafer surface. The secure attachment between the first wafer 104 and flexible wafer chuck 102 ensure that the controlled deformation of the chuck transfers precisely to the wafer. In various embodiments, the upper surface of the flexible wafer chuck 102 may also comprise alignment features or fiducial marks to assist in the initial positioning of the first wafer 104. During operation, the flexible wafer chuck 102 maintains secure contact with the first wafer 104 throughout the deformation and bonding process, ensuring that the first wafer 104 follows the flexible wafer chuck's custom deformation pattern designed to compensate for the wafer's anisotropic mechanical properties.

In various embodiments, the flexible wafer chuck 102 may comprise a pressure chamber 130 that is separated from the first wafer 104 by a wall 132. In various embodiments, a thickness of the wall 132 may vary based on both angular position and radial distance from the center, allowing for anisotropic deformation when the pressure chamber 130 is pressurized. The cross-sectional view of the wafer bonding apparatus 100 along line 1A-1A′ illustrates a first thickness profile T₁ of the wall 132, corresponding to a first angle β₁ from the x-axis as shown in FIG. 1D. In various embodiments, the first thickness profile T₁ may comprise a wall thickness that varies based on a radial distance from the center of the wall 132, allowing for customized deformation along the radial direction when viewed from the first angle β₁. In some embodiments, the first thickness profile T₁ may follow a specific mathematical function, such as a polynomial or exponential relationship, designed to create customized deformation patterns when pressure is applied to the pressure chamber 130.

In various embodiments, the wafer bonding apparatus 100 may further comprise a gas flow line 122 and a vacuum line 124 coupled to the pressure chamber 130 and configured to control the pressure within the pressure chamber 130. In one or more embodiments, the gas flow line 122 may be connected to a gas source, such as a pressurized gas tank containing nitrogen, argon, or clean dry air. The gas flow line 122 may comprise pressure regulators, filters, and flow meters to ensure precise control of gas flow into the pressure chamber 130 through a valve 120. In one or more embodiments, the vacuum line 124 may be connected to a vacuum pump system capable of evacuating the pressure chamber 130 to create controlled decompression. Both the gas flow line 122 and vacuum line 124 may be coupled to the pressure chamber 130 through the valve 120 with sealed ports that maintain pressure integrity.

In various embodiments, the valve 120 may be positioned along these lines to control the flow of gas and vacuum into the pressure chamber 130. In one or more embodiments, the valve 120 may be a multi-port valve capable of switching between gas flow, vacuum, and states with various opening percentage (from fully closed to fully open) to adjust flow rate. In some embodiments, separate valves may be used for the gas flow line 122 and the vacuum line 124 to provide more precise control. In various embodiments, these valves may be electronically controlled solenoid valves or pneumatically actuated valves designed for high-precision applications.

In one or more embodiments, the flexible wafer chuck 102 may further comprise one or more pressure sensors positioned within the pressure chamber 130 to provide real-time monitoring of chamber pressure conditions. In some embodiments, the pressure sensors may be high-precision capacitive or piezoresistive transducers capable of measuring pressure with accuracy in the range of 0.1% or better of full scale. In various embodiments, multiple pressure sensors may be strategically placed at different locations within the pressure chamber 130 to detect any pressure gradients or non-uniformities that might affect the deformation pattern.

In various embodiments, the wafer bonding apparatus 100 may comprise a wafer carrier 108 configured to hold and align a second wafer 106 above the first wafer 104. The wafer carrier 108 may comprise materials with high dimensional stability, such as ceramic or metal alloys with low thermal expansion coefficients, to maintain positional accuracy during the bonding process. The second wafer 106 may comprise similar materials of the first wafer 104 as described above. In one or more embodiments, the wafer carrier 108 may comprise a vacuum zone on its lower surface that interfaces with the second wafer 106. This vacuum zone may comprise a network of channels and ports connected to a vacuum source, creating suction that securely holds the second wafer 106 against the wafer carrier 108.

In some embodiments, a striker 110 may be positioned above the second wafer 106 and configured to apply controlled downward force towards the second wafer 106 during the bonding operation. In one or more embodiments, the striker 110 may be actuated by pneumatic, hydraulic, or electromechanical systems that provide precise control over the applied force and movement speed. During the bonding operation, the striker 110 may descend to contact the second wafer 106, applying pressure that initiates contact between the second wafer 106 and the first wafer 104. The contact may begin at the center and propagate outward in a controlled manner, minimizing trapped air and ensuring uniform bonding across the entire wafer surface.

While the embodiments described above illustrate bond propagation initiated using a striker mechanism (through the striker 110), other bond propagation methods may also be employed with the flexible wafer chuck 102 of the present disclosure. For example, in some embodiments, bond propagation may be initiated using thermal energy applied at the center of the wafers through a localized heating element. In other embodiments, acoustic or ultrasonic energy may be used to initiate and promote bond propagation. Some implementations may utilize mechanical pressure applied through a rolling mechanism that progressively moves across the wafer surface. In alternative embodiments, bond propagation may be facilitated by specialized surface treatments or by creating atmospheric pressure differentials between the bonding interface and the surrounding environment. These alternative bond propagation methods may be selected based on specific material requirements, surface conditions, or particular bonding applications, while still benefiting from the direction-dependent deformation capabilities of the flexible wafer chuck described herein.

In various embodiments, the wafer bonding apparatus 100 may further comprise an alignment system coupled to the wafer carrier 108 and the flexible wafer chuck 102 to ensure precise alignment between the second wafer 106 and the first wafer 104. In some embodiments, the alignment system may utilize infrared (IR) imaging to detect alignment marks on both wafers. In some embodiments, the alignment system may comprise multiple cameras positioned at different angles to capture alignment marks at various locations across the wafer surface, enabling compensation for any rotational or scaling misalignments.

In various embodiments, the alignment system may be coupled to actuators attached to the wafer carrier 108, allowing for nanometer-scale adjustments in x, y, and rotational positions. These actuators may employ piezoelectric or voice coil technologies for high-precision movement without backlash. During the alignment process, the alignment system may continuously monitor the position of alignment marks on both wafers (e.g., the first and the second wafers 104 and 106) and make real-time adjustments to the wafer carrier 108 position until optimal alignment is achieved.

In one or more embodiments, a controller 190 may be coupled to multiple components of the wafer bonding apparatus 100 to provide integrated control of the entire bonding process. In various embodiments, the controller 190 may be coupled to the valve 120, flexible wafer chuck 102, wafer carrier 108, and the alignment system. In one or more embodiments, the controller 190 may be coupled to the gas flow line 122 and vacuum line 124 through the valve 120 to control the gas flow or vacuum condition in the pressure chamber 130. The integrated control may enable coordinated operation of all components to achieve optimal bonding results. In various embodiments, the controller 190 may comprise a central processing unit (CPU) that executes the control algorithms, memory components for storing operational parameters and process recipes, and input/output interfaces for communicating with the various apparatus components. The memory components may comprise both volatile memory (RAM) for active processing and non-volatile memory (flash memory or solid-state drives) for storing process recipes, calibration data, and historical performance data.

In some embodiments, the CPU of the controller 190 may be configured to execute: control a flow rate of gas into the pressure chamber 130 through the gas flow line 122; regulate pressure within the pressure chamber 130 to achieve the anisotropic deformation in the wall 132 which may induce corresponding anisotropic deformation in the first wafer 104; and control evacuation of gas from the pressure chamber 130 through the vacuum line 124 to remove the anisotropic deformation in the wall 132 and the first wafer 104.

In various embodiments, the controller 190 may execute software that simultaneously manages multiple aspects of the bonding process. For chamber pressure control, the software may monitor pressure sensors within the pressure chamber 130 and adjust the valve 120 settings to achieve the desired pressure profile. For wafer alignment control, the software may process data from the alignment system to make fine adjustments to the wafer carrier 108 position while coordinating with the chamber pressure control to optimize wafer deformation. The controller 190 may also comprise a user interface, such as a touchscreen display or network connection, allowing operators to program specific process parameters, monitor system status, and retrieve process data.

In one or more embodiments, the wafer bonding apparatus 100 may comprise feedback mechanisms for enhanced precision. In one embodiment, pressure sensors within the pressure chamber 130 may continuously report pressure values to the controller 190, which then makes real-time adjustments to the valve 120 settings which may include opening percentage (from fully closed to fully open), flow rate regulation, and switching between gas flow and vacuum modes. In various embodiments, the controller 190 may send electronic signals to electromechanical actuators coupled to the valve 120, which may include proportional solenoid valves, piezoelectric valve controllers, or servo-motor driven ball valves that can be precisely positioned to achieve the desired gas flow or vacuum level through the gas flow line 122 or the vacuum line 124. In some implementations, the controller 190 may adjust multiple valve parameters simultaneously, such as modulating both the inlet and outlet valves to maintain a specific pressure ramp rate within the pressure chamber 130. In some embodiments, the controller 190 may be coupled to additional valves positioned along gas flow line 122 and vacuum line 124 to provide redundant or more granular control of gas flow and vacuum operations. In some embodiments, the alignment system may provide continuous position data that the controller 190 uses to refine the wafer carrier 108 position. This closed-loop control system ensures that both the pressure profile and alignment parameters follow predetermined patterns necessary to create the optimal anisotropic deformation in the flexible wafer chuck 102 while maintaining precise wafer-to-wafer alignment.

In various embodiments, the first and second wafers 104 and 106 may undergo a plasma activation prior to wafer bonding. In one or more embodiments, the first wafer 104 and second wafer 106 may be subjected to plasma treatment before being placed on the flexible wafer chuck 102 and wafer carrier 108, respectively. The plasma activation may utilize oxygen, nitrogen, argon, or combinations thereof to create reactive surface groups on both wafer surfaces. In one or more embodiments, the wafer bonding may comprise a hybrid direct bonding method where the plasma activation may prepare both the dielectric surfaces and exposed metal features (such as copper pads) on the wafers. The dielectric surfaces may form hydroxyl groups (—OH) that enable direct bonding, while the metal features may be cleaned of oxides to facilitate metal-to-metal bonding. In various embodiments, the plasma activation may be performed at low temperatures, for example, between room temperature and 200 °C, making it compatible with temperature-sensitive materials and devices. This surface preparation may help achieve high-quality bonds with alignment accuracy better than 100 nanometers, as required for advanced semiconductor integration. When the second wafer 106 contacts with the first wafer 104 during the bonding process, the reactive surfaces may form initial bonds that strengthen during subsequent processing steps.

Referring to FIG. 1B, which illustrates a cross-sectional view of the wafer bonding apparatus 100 along line 1B-1B′ as shown in FIG. 1D, in accordance with an embodiment. This cross-section is taken at a second angle β₂ from the x-axis, where the second angle β₂ may differ from the first angle β₁.

FIG. 1B differs from FIG. 1A in the cross-sectional view of the wall 132. Along the cross-section at the second angle β₂, the wall 132 may exhibit a second thickness profile T₂, which may differ from the first thickness profile T₁ observed in FIG. 1A. In various embodiments, the second thickness profile T₂ may comprise a thickness that varies based on a radial distance from the center of the flexible wafer chuck 102. The second thickness profile T₂ may be designed to differ from the first thickness profile T₁ to create angle-dependent deformation characteristics in the flexible wafer chuck 102.

FIG. 1C illustrates a cross-sectional view of the wafer bonding apparatus 100 along line 1C-1C′ as shown in FIG. 1D, in accordance with an embodiment. The 1C-1C′ cross-section is taken at a third angle β₃ from the x-axis, where the third angle β₃ may differ from both the first angle β₁ and the second angle β₂.

FIG. 1C differs from FIGS. 1A and 1B in the cross-sectional view of the wall 132. Along the cross-section at the third angle β₃, the wall 132 may exhibit a third thickness profile T₃, which may differ from both the first thickness profile T₁ observed in FIG. 1A and the second thickness profile T₂ observed in FIG. 1B. In various embodiments, the third thickness profile T₃ may comprise a thickness that varies based on a radial distance from the center of the flexible wafer chuck 102. The third thickness profile T₃ may be designed to differ from the first and second thickness profiles T₁ and T₂ to create angle-dependent deformation characteristics in the flexible wafer chuck 102.

For clarity, it should be noted that while the valve 120, vacuum line 124, and gas flow line 122 are shown in each of the cross-sectional views in FIGS. 1A-1C, the wafer bonding apparatus 100 may comprise only one set of these components. They are depicted in each cross-sectional view for illustration purposes to show their relationship to the pressure chamber 130 regardless of the viewing angle.

To compensate for the anisotropic misalignment caused by the wafer stretching during bond propagation, the wafer bonding apparatus 100 described in FIGS. 1A-1D may comprise anisotropic deformation capabilities to expand the first wafer 104 in a complementary anisotropic pattern before bonding. By creating a customized deformation pattern that varies with angular and radial positions, the flexible wafer chuck 102 may pre-deform the first wafer 104 to match the anticipated anisotropic stretching of the second wafer 106, particularly for wafers with (111), (100), or (110) orientations, thereby reducing wafer misalignment during bonding.

As illustrated in FIGS. 1A-1C, the wall 132 of the flexible wafer chuck 102 may be configured with thickness variations that enable it to deform anisotropically when pressure is applied to the pressure chamber 130. These thickness variations are based on both the radial distance from the center point of the wall 132 and the angular position relative to the center point. The wall 132 exhibits different thickness profiles (e.g., T₁, T₂, and T₃) when viewed along different angular positions (e.g., β₁, β₂, and β₃), respectively. Each thickness profile may also vary along its radial direction. The thickness distribution may be specifically designed to accommodate the anisotropic mechanical properties of silicon wafers, particularly the varying elasticity along different crystallographic directions. In various embodiments, each thickness profile may follow its own mathematical function, with parameters selected to achieve the desired deformation characteristics along each specific angular direction. When pressure is applied to the pressure chamber 130, these thickness variations may cause the wall 132 to deform by different amounts in different directions, creating a customized anisotropic deformation pattern in the flexible wafer chuck 102 that compensates for the directionally-varying stretching behavior of silicon during the wafer bonding process.

In various embodiments, the flexible wafer chuck 102 may comprise a material with varying mechanical properties (such as a Young's modulus) that vary based on radial or angular position within the flexible wafer chuck 102. The variations in mechanical properties may be configured to contribute to the anisotropic deformation of the wall 132 when pressure is applied to the pressure chamber. In some embodiments, the material composition along cross-section 1A-1A′ may comprise a polymer blend or composite material with a first Young's modulus, while the material along cross-section 1B-1B′ may comprise a different polymer blend or composite material with a second Young's modulus that differs from the first Young's modulus. When pressure is applied to the pressure chamber 130, the material along cross-section 1A-1A′ may deform with a first amount of displacement, while the material along 1B-1B′ may deform with a second, different amount of displacement due to its different mechanical properties. The different amount of displacement may anisotropically deform the wall 132, thereby anisotropically deforming the first wafer 104. In one or more embodiments, the differences in material mechanical properties may work in conjunction with the thickness variations of wall 132 to create a combined anisotropic response to applied pressure. In an embodiment, the flexible wafer chuck 102 may comprise functionally graded materials where the Young's modulus gradually transitions between different values along the radial or angular directions, creating smooth variations in deformation characteristics. The combined effect of these anisotropic material properties and thickness profiles may result in a precisely controlled anisotropic deformation of the wall 132, which transfers to the first wafer 104 to create the optimal deformation pattern needed to compensate for silicon's anisotropic mechanical properties during the bonding process.

FIGS. 2A-2D and 3A-3D illustrate cross-sectional views of a method for wafer-to-wafer bonding using the wafer bonding apparatus 100 described in FIGS. 1A-1D, in accordance with an embodiment. FIGS. 2A-2D illustrate the cross-sectional views along line 1A-1A′ shown in FIG. 1D, while FIGS. 3A-3D illustrate the cross-sectional views along line 1B-1B′ shown in FIG. 1D. Components and features in FIGS. 2A-2D and 3A-3D that share reference numbers with those in FIGS. 1A-1D have corresponding structures and materials as previously described. The cross-sectional views along different angles (1A-1A′ with the first angle β₁ versus 1B-1B′ with the second angle β₂) illustrate how the wall 132 with its varying thickness profiles T₁ and T₂ creates different deformation patterns along different directions when pressure is applied to the pressure chamber 130.

FIGS. 2A and 3A illustrate a step in the wafer bonding process where pressure is applied to the pressure chamber 130, in accordance with an embodiment. In FIG. 2A, which shows a cross-sectional view along line 1A-1A′, a gas flow 210 may enter the pressure chamber 130 through the gas flow line 122 and the valve 120. The gas may create pressure 230 that acts on the wall 132 of the flexible wafer chuck 102. In various embodiments, the pressure 230 may be continuously monitored by pressure sensors positioned inside the pressure chamber 130 and regulated by the controller 190 until a targeted pressure level or desired deformation of wall 132 is achieved.

In one or more embodiments, the pressure 230 may cause the wall 132 to deform in the cross-section 1A-1A′ at a first amount of deformation, which in turn creates a corresponding deformation in the first wafer 104. The first amount of deformation may be directly related to the first thickness profile T₁ of the wall 132 or the materials composition along this cross-section. In some embodiments, the controller 190 may precisely adjust the pressure 230 based on real-time feedback from the pressure sensors to achieve the exact deformation pattern required to compensate for the anisotropic mechanical properties of silicon along this particular cross-section.

FIG. 3A shows the same process step but viewed along the cross-section 1B-1B′, which is at the second angle β₂ from the x-axis. The pressure 230 applied to the pressure chamber 130 may cause the wall 132 to deform at a second amount of deformation due to the second thickness profile T₂ or materials composition along this cross-section. In embodiments where the thickness profile T₁ may be smaller than thickness profile T₂, the first amount of deformation along the cross-section 1A-1A′ may be greater than the second amount of deformation along the cross-section 1B-1B′. In embodiments where the Young's modulus of the material along the cross-section 1A-1A′ is smaller than that along the cross-section 1B-1B′, the amount of deformation in response to the same applied pressure may be greater along the cross-section 1A-1A′, creating an additional mechanism for achieving anisotropic deformation patterns in the flexible wafer chuck 102. This difference in deformation response to the same applied pressure creates the anisotropic deformation pattern necessary to properly compensate for silicon's anisotropic mechanical properties. In some embodiments, the first wafer 104 may be a (100) silicon wafer and the flexible wafer chuck 102 may be anisotopically deformed to form a height map similar to the height map of FIG. 6C which will be described below.

In various embodiments, the controller 190 may analyze data from multiple pressure sensors or position sensors to verify that the anisotropic deformation of the first wafer 104 follows the predetermined pattern designed for optimal alignment with the second wafer 106. In one or more embodiments, the gas flow 210 may be adjusted in real-time to fine-tune the pressure 230, ensuring that the deformation along each direction precisely matches the required values calculated based on the specific crystal orientation and mechanical properties of the wafers being bonded.

FIGS. 2B and 3B illustrate the next step in the wafer bonding process after the pressure is applied to deform the flexible wafer chuck 102, in accordance with an embodiment.

In FIG. 2B, which shows a cross-sectional view along line 1A-1A′, the second wafer 106 may be aligned over the first wafer 104 and held by the wafer carrier 108. The alignment may be performed with high precision using the alignment system described earlier, which ensures that the features on both wafers are properly positioned relative to each other. In one or more embodiments, the pressure 230 may continue to be maintained in the pressure chamber 130, keeping the first wafer 104 in its deformed state according to the first thickness profile T₁ along cross-section 1A-1A′. In some embodiments, the valve 120 may turn off the gas flow 210 to maintain the pressure in the pressure chamber 130. The deformation may be controlled to compensate for the anticipated stretching of the second wafer 106 during bond propagation along this cross-section.

In various embodiments, the wafer carrier 108 may lower the second wafer 106 until it contacts the first wafer 104. In one or more embodiments, the striker 110 may apply controlled pressure to the second wafer 106, initiating contact at the center of the wafers. This contact point may serve as the starting location for subsequent bond propagation. The pressure applied by the striker 110 may be carefully regulated to ensure proper initial contact without causing damage to the wafers. The controller 190 may adjust the striker pressure based on feedback from force sensors to achieve optimal contact conditions.

FIG. 3B shows the same process step but viewed along the cross-section 1B-1B′. The first wafer 104 may be deformed according to the second thickness profile T₂ along cross-section 1B-1B′, which may differ from the deformation shown in FIG. 2B due to the direction-dependent characteristics of the flexible wafer chuck 102.

FIGS. 2C and 3C illustrate the bond propagation step of the wafer bonding process, in accordance with an embodiment.

In FIG. 2C, which shows a cross-sectional view along line 1A-1A′, the vacuum holding the second wafer 106 to the wafer carrier 108 may be released as bond propagation occurs. In one or more embodiments, the release may allow the second wafer 106 to stretch and temporarily bond with the first wafer 104. In some embodiments, the bond propagation may begin at the center contact point and may spread outward in a wave-like pattern. As bonding propagation occurs, the second wafer 106 may stretch due to the surface forces at the bonding interface. In various embodiments, the pressure 230 may continue to be maintained in the pressure chamber 130, keeping the first wafer 104 in its deformed state according to the first thickness profile T₁ along this cross-section. In various embodiments, the release of vacuum from the wafer carrier 108 may be timed and coordinated with the bond propagation to optimize the bonding process. The controller 190 may monitor the bond front progression using sensors and may adjust the vacuum release rate accordingly.

FIG. 3C shows the same process step but viewed along cross-section 1B-1B′. Here, the bond propagation may similarly progress outward from the center, with the second wafer 106 stretching as it bonds to the first wafer 104. In various embodiments, the first wafer 104 may remain deformed according to the second thickness profile T₂ along this cross-section, which may differ from the deformation shown in FIG. 2C due to the direction-dependent characteristics of the flexible wafer chuck 102.

In both figures, the initial contact between the two wafers may initiate the bond propagation that spreads outward from the center in subsequent steps. The anisotropic deformation created by the flexible wafer chuck 102 may ensure that as the bond propagates outward and the second wafer 106 stretches, the first wafer 104 may be pre-deformed in a complementary pattern that may maintain alignment across the entire wafer surface. This anisotropic pre-deformation may compensate the anisotropic stretching behavior of silicon during bonding, particularly for silicon wafers with (100) or (110) crystal orientations.

FIGS. 2D and 3D illustrate formation of direct wafer bonding, in accordance with an embodiment.

In FIG. 2D, which shows a cross-sectional view along line 1A-1A′, the gas may be vacuumed out of the pressure chamber 130 through the vacuum line 124 and valve 120 (following a gas arrow 220). The gas evacuation may release the pressure 230 that was maintaining the deformation of the flexible wafer chuck 102, allowing the wall 132 to return to its undeformed state. As the flexible wafer chuck 102 flattens, the direct bonded wafers comprising the first wafer 104 and second wafer 106 may also flatten. The controller 190 may regulate the evacuation rate to ensure a controlled, gradual release of the deformation, which may help prevent any sudden movements that could affect bond quality.

FIG. 3D shows the same process step but viewed along cross-section 1B-1B′. Here, the evacuation of the pressure chamber 130 may similarly allow the flexible wafer chuck 102 to return to its undeformed state along this cross-section. The different deformation patterns that were present along the 1A-1A′ and 1B-1B′ cross-sections may be simultaneously removed as the pressure is released, resulting in a flat, bonded wafers.

In various embodiments, the direct bonded wafers with plasma-activated surfaces (as described with reference to FIG. 1A) may be ready for bond strengthening. The plasma-activated surfaces of the first wafer 104 and second wafer 106 may have already formed initial bonds during contact and bond propagation. These bonds may be further strengthened through low-temperature annealing, which may convert the initial hydrogen bonds into stronger covalent bonds, creating a permanent hybrid bond between the wafers. In one or more embodiments, the direct bonded wafers may be annealed at temperatures ranging from 200 °C to 400 °C, which may be lower than conventional fusion bonding temperatures, making it compatible with temperature-sensitive materials and metal interconnects.

While FIGS. 2A-2D and 3A-3D illustrate the main steps of the wafer bonding process along two specific cross-sections, additional steps that are not illustrated may be incorporated into the process. In some embodiments, prior to placing the first wafer 104 on the flexible wafer chuck 102, a wafer cleaning and surface preparation step may be performed to remove contaminants and ensure optimal bonding conditions. In some embodiments, an alignment verification step may be performed after the initial alignment but before contact to confirm proper positioning of features between the wafers. In some embodiments, after bond propagation but before releasing the pressure from the pressure chamber 130, a bond quality verification step may be performed using infrared imaging or acoustic microscopy to detect any voids or defects in the temporary bond. In additional embodiments, after completing the bonding process, the bonded wafers may undergo inspection, metrology, and testing steps to verify alignment accuracy, bond strength, and electrical connectivity between the bonded wafers.

Note that the cross-sectional views shown in FIGS. 2A-2D and 3A-3D are provided for illustration purposes to demonstrate the anisotropic deformation capability of the flexible wafer chuck 102. It should be understood that the wafer may experience different deformation patterns along different cross-sections beyond just those shown. For example, along cross-section 1C-1C′ (not illustrated in the bonding sequence), the first wafer 104 may experience yet another amount of deformation corresponding to the third thickness profile T₃ of the wall 132. The flexible wafer chuck 102 may create a comprehensive three-dimensional deformation pattern that varies continuously with angular position around the wafer, not just along the two illustrated cross-sections. This continuous variation in deformation characteristics enables the wafer bonding apparatus 100 to precisely compensate for the anisotropic mechanical properties of silicon wafers, regardless of the specific direction being considered.

FIG. 4A illustrates an alternative embodiment of a wafer bonding apparatus 400 featuring a plurality of pressure chambers, in accordance with an embodiment. The wafer bonding apparatus 400 may comprise a flexible wafer chuck 402 configured to hold the first wafer 104. The flexible wafer chuck 402 may comprise similar materials and operations to those described for the flexible wafer chuck 102. Components sharing the same reference numbers as previously described (such as the first wafer 104, second wafer 106, wafer carrier 108, and striker 110) may have the same structures, materials, and functions as described earlier.

In various embodiments, the flexible wafer chuck 402 may comprise a plurality of pressure chambers 430a (a first pressure chamber), 430b (a second pressure chamber), and 430c (a third pressure chamber) within its structure. A wall 432 may separate the plurality of pressure chambers from the first wafer 104. In one or more embodiments, each pressure chamber may have a different volume, shape, or position within the flexible wafer chuck 402. For example, the first pressure chamber 430a may comprise a first volume, while the second pressure chamber 430b may comprise a second volume that differs from the first volume. The third pressure chamber 430c may comprise yet another different volume. In various embodiments, each of the plurality of pressure chambers 430a, 430b, and 430c may be coupled to its own valve 420, gas flow line 422 and vacuum line 424, allowing for independent control of pressure within each chamber.

In various embodiments, a controller 490 may be coupled to the plurality of valves 420, gas flow lines 422, vacuum lines 424, the wafer carrier 108, and the flexible wafer chuck 402. The controller 490 may independently control the pressure within each of the plurality of pressure chambers 430a, 430b, and 430c. In various embodiments, the controller 490 may comprise similar components and functions as the controller 190 of the wafer bonding apparatus 100 described with reference to FIG. 1A.

FIG. 4B illustrates an operation of deforming the flexible wafer chuck 402 by applying pressures to the plurality of pressure chambers, in accordance with an embodiment. In various embodiments, the controller 490 may be configured to independently control gas flow into each of the plurality of pressure chambers through their respective gas flow lines 422. In various embodiments, the controller 490 may be coupled to the plurality of gas flow lines 422 and vacuum lines 424 through the plurality of valves 420. In various embodiments, the controller 490 may regulate each gas flow by sending electronic signals to the valves 420 positioned along each gas flow line 422, with separate valves controlling the flow to each of the pressure chambers 430a, 430b, and 430c. The valves 420 may be proportional control valves that can be adjusted to precise opening positions, allowing for fine control of gas flow rates into each chamber. In some embodiments, the controller 490 may adjust the valve openings based on pressure feedback, predetermined pressure profiles, or in response to alignment measurements during the bonding process. The controller 490 may therefore independently regulate pressure within each of the plurality of pressure chambers 430a, 430b, and 430c that differently deform the wall 432 between the first wafer 104 with each pressure chamber. In various embodiments, the pressure may anisotropically deform the first wafer 104 in a pattern specifically designed to compensate for anisotropic mechanical properties of the wafer.

In various embodiments, FIG. 4B may serve a similar role in the bonding process as FIG. 2A, representing the initial deformation stage of the flexible wafer chuck prior to wafer contact. After achieving the desired deformation pattern through independent pressure control of the pressure chambers as shown in FIG. 4B, the process may proceed through subsequent steps similar to those illustrated in FIGS. 2B through 2D to complete the bonding operation. In various embodiments, the second wafer 106 may be aligned over the deformed first wafer 104 and brought into contact using the striker 110 (similar to FIG. 2B). Bond propagation may then occur as the vacuum holding the second wafer 106 is released, allowing it to stretch and temporarily bond with the first wafer 104 (similar to FIG. 2C). In one or more embodiments, after bond propagation, the controller 490 may be configured to independently control evacuation of gas from the plurality of pressure chambers through the plurality of vacuum lines 424 to reduce pressures within each of the plurality of pressure chambers (430a, 430b, and 430c) in a controlled sequence to flatten the bonded wafers (similar to FIG. 2D).

In various embodiments, the operation illustrated in FIG. 4B may represent one of many possible pressure configurations that may be implemented by the controller 490. Different wafer types, crystal orientations, or specific bonding requirements may be implemented with different pressure distributions among the pressure chambers. The controller 490 may store multiple pressure profiles in its memory and select the appropriate profile based on the specific wafers being bonded. In one or more embodiments, the controller 490 may dynamically adjust the pressures in real-time based on feedback from sensors monitoring the deformation or alignment during the bonding process, creating an adaptive control system that optimizes alignment accuracy for each specific bonding operation.

In various embodiments, each of the plurality of pressure chambers may be pressurized to different levels to create targeted deformation patterns in specific areas of the wafer. In one embodiment, one pressure chamber such as 430a may be operated at a higher pressure to induce a greater deformation range in a particular region of the flexible wafer chuck 402, and consequently in the corresponding region of the first wafer 104, to compensate for localized misalignment that may arise during bonding. In many embodiments, the wall 432 separating the plurality of pressure chambers from the first wafer 104 may comprise similar anisotropic features to those described for wall 132 in FIG. 1A, in that it may have thickness variations or component material variations based on angular position or radial distance from the center. These variations may be independently designed for each pressure chamber region, creating a comprehensive deformation capability that combines both regional control through multiple chambers and direction-dependent control through anisotropic wall properties.

FIGS. 5A-5C illustrate the anisotropic mechanical properties of silicon wafers with different crystal orientations and the resulting scaling patterns during bonding, in accordance with an embodiment.

FIG. 5A shows a polar plot of 1/E (the inverse of Young's modulus) for silicon wafers with different crystal orientations, demonstrating how the elasticity varies with direction. FIG. 5A illustrates three different patterns: curve 502 representing (111) silicon surface, curve 504 representing (100) silicon surface, and curve 506 representing (110) silicon surface. The silicon surfaces may show directional variations in elasticity, with the (110) surface displaying higher anisotropy between different crystallographic directions.

FIG. 5B illustrates a top view of an isotropic scaling pattern in a silicon wafer during bond propagation. The arrows indicate the direction of scaling, with darker regions indicating greater scaling. The top wafer may stretch isotropically in all directions (e.g., along the x-axis, y-axis, and 45-degree directions) during bond propagation. This uniform stretching can be adequately compensated using conventional flexible wafer chucks that expand the bottom wafer with isotropic deformation patterns.

FIG. 5C depicts the anisotropic scaling pattern for a silicon wafer (e.g., silicon wafer with (100) crystal orientation) with anisotropic mechanical properties during bond propagation. The top wafer stretches differently depending on direction. For example, the stretching along the x and y axes may be similar in magnitude but different from the stretching along the 45-degree directions. This directional variation in stretching may not be properly compensated using conventional chucks with isotropic deformation characteristics, resulting in residual misalignment after bonding.

In various embodiments, the wafer misalignment resulting from wafer stretching may be quantified using measurement index equations shown below:

dxᵢ=Tx+Sx*Xᵢ−Rot*Yᵢ+Randomₓᵢ (Equation 1)

dyᵢ=Ty+Sy*Yᵢ−Rot*Xᵢ+Random_{yi} (Equation 2)

where dxᵢ and dyᵢ represent the measured misalignment values along the x and y axes respectively, Tx and Ty represent translational misalignment components, Sx and Sy represent scaling factors (related to the stretching during bond propagation), Xᵢ and Yᵢ are the coordinate positions, Rot represents rotational misalignment, Randomₓᵢ and Random_{yi} represent residual, non-correctable misalignment components.

When analyzing wafer bonding misalignment, the Equations 1 and 2 may help decompose the total misalignment into different components. The translation component may represent a uniform shift of the entire pattern. The scaling component may represent expansion or contraction that increases with distance from the center. The rotation component may represent a circular displacement around the center. The random component may represent the residual misalignment that remains after accounting for translation, scaling, and rotation. In one or more embodiments, the remaining residual pattern for (100) silicon wafers may exhibit a characteristic 4-fold symmetry as a 4-fold residual.

FIGS. 6A-6C illustrate top views of height maps representing the deformation patterns of the flexible wafer chuck 102 or 402 during wafer bonding process, in accordance with various embodiments. In various embodiments, the height maps show the vertical displacement of surface of the flexible wafer chuck 102 or 402 when pressure is applied to the pressure chamber 130. Different contour lines in the height maps may indicate different height values where the contour lines closer to the center point of the flexible wafer chuck 102 or 402 may have greater value.

FIG. 6A shows the height map of a conventional flexible wafer chuck. The conventional chuck may create a radially symmetric deformation pattern (or isotropic deformation pattern), with circular contour lines indicating that the deformation is uniform in all directions from the center. The height gradually decreases from the center toward the edge in a consistent manner regardless of angular position.

FIG. 6B depicts a height map designed to reduce 4-fold residuals that result from the anisotropic mechanical properties of silicon wafers. Unlike the circular contours in FIG. 6A, the height map in FIG. 6B may show a more square-like pattern with different height profiles along different directions. The height profile along the x and y axes may differ from the height profile along the 45-degree directions, creating a pattern that specifically targets the 4-fold symmetry observed in residual misalignment patterns.

FIG. 6C illustrates the height map of the flexible wafer chuck 102 or 402 for (100) silicon wafers, which may be a combination of the isotropic pattern shown in FIG. 6A and the 4-fold residual compensation pattern shown in FIG. 6B. The combined height map may enable comprehensive compensation for the anisotropic deformation that occurs during (100) wafer bonding.

In various embodiments, the customized height maps of the flexible wafer chuck 102 or 402 may be achieved through the direction-dependent thickness or material component variations of the wall 132 described in FIGS. 1A-1D (or the wall 432 described in FIGS. 4A and 4B). When pressure is applied to the pressure chamber 130 or the plurality of pressure chambers 430a-c, the wall 132 or 432 may deform according to its thickness profile, materials component, or chamber pressures, creating customized height maps to induce desired anisotropic deformation in the wafer. This approach enables the wafer bonding apparatus 100 or 400 to achieve high alignment accuracy for wafers with anisotropic mechanical properties.

While FIG. 6C illustrates one example of customized height maps designed for (100) silicon wafers, the flexible wafer chuck 102 or 402 may be engineered to create various complex height maps tailored to specific wafer types and bonding requirements. In one embodiment, the flexible wafer chuck 102 or 402 may be designed with an elongated elliptical height map to compensate for the mechanical anisotropy of (110) silicon wafers. In another embodiment, the flexible wafer chuck 102 or 402 may create more complex deformation patterns designed for wafers that have undergone specific processing steps such as selective ion implantation, localized thermal oxidation, or stress-inducing film deposition, which may create regionally varying mechanical properties within the same wafer. The wafer bonding apparatus 100 or 400 may provide a versatile platform where the specific thickness profiles, material selections, and pressure chamber configurations can be customized to address the particular anisotropic deformation characteristics of various wafer types and conditions encountered in advanced semiconductor manufacturing processes.

FIG. 7 illustrates performance data comparing residual misalignment between a conventional flexible wafer chuck and the customized flexible wafer chuck (e.g., the flexible wafer chucks 102 and 402) described in this disclosure, in accordance with an embodiment. The horizontal axis represents the height of deformation at the center of the chuck in micrometers (μm). The vertical axis represents the mean+3σ 4-term residual misalignment in nanometers (nm).

In various embodiments, a curve 704 may represent data from a conventional flexible wafer chuck, and a curve 702 may represent data from the customized flexible wafer chuck with anisotropic deformation capabilities as described in this disclosure. Both curves show performance results when bonding (100) silicon wafers, which exhibit the anisotropic mechanical properties discussed earlier.

In various embodiments, the curve 704 shows that with a conventional flexible wafer chuck, the 4-term residual misalignment remains relatively constant regardless of the height of deformation. This indicates that while increasing the deformation height of the conventional wafer chuck may compensate for isotropic scaling, it cannot address the anisotropic residual misalignment caused by silicon's anisotropic mechanical properties.

In one or more embodiments, the curve 702 shows that with the customized flexible wafer chuck (e.g., the flexible wafer chucks 102 and 402) featuring anisotropic deformation capabilities, the residual misalignment decreases as the height of deformation increases. The data demonstrates that the anisotropic deformation pattern created by the customized flexible wafer chuck may compensate for the anisotropic scaling of the (100) silicon wafer during bond propagation.

FIG. 8 illustrates cumulative probability distributions of misalignment for bonded wafers using different wafer chuck technologies, in accordance with an embodiment. The horizontal axis represents misalignment in nanometers (nm), while the vertical axis shows the cumulative probability, indicating the percentage of measurement points across the wafer that achieve misalignment values below a given threshold. The graph features two curves: a curve 804 representing results from a conventional flexible wafer chuck, and a curve 802 representing results from the customized flexible wafer chuck (e.g., the flexible wafer chucks 102 and 402) with anisotropic deformation capabilities.

At a critical misalignment threshold value indicated by line 800 (which may represent a specification limit for a particular semiconductor manufacturing process), the customized flexible wafer chuck (curve 802) demonstrates a higher cumulative probability compared to the conventional chuck (curve 804). This indicates that a larger percentage of the wafer area meets the alignment requirements when using the customized flexible wafer chuck with anisotropic deformation capabilities. The steeper slope of curve 802 also suggests more consistent alignment across the wafer surface, with fewer outlier regions exhibiting high misalignment. This improved alignment yield directly translates to higher manufacturing yield and better device performance in advanced semiconductor applications.

FIG. 9 illustrates a flow diagram of a method for wafer bonding using a flexible wafer chuck with anisotropic deformation capabilities, in accordance with an embodiment.

At block 902, a first wafer may be placed over a flexible wafer chuck, the flexible wafer chuck comprising a pressure chamber, wherein a wall of the flexible wafer chuck may separate the pressure chamber from the first wafer. This step may correspond to the configuration shown in FIG. 1A, where the first wafer 104 may be placed on the flexible wafer chuck 102 with the wall 132 separating the pressure chamber 130 from the first wafer 104. In various embodiments, the flexible wafer chuck may comprise the materials described with reference to FIGS. 1A-1D, such as polymer materials including polyimide, PDMS, PEEK, or other suitable materials.

At block 904, a gas may be flowed into the pressure chamber to apply a pressure to the wall of the pressure chamber to anisotropically deform the first wafer to compensate for anisotropic mechanical properties of the first wafer. This step may correspond to the processes illustrated in FIGS. 2A and 3A, where gas flow 210 may enter the pressure chamber 130 creating pressure 230 that deforms the wall 132 and consequently the first wafer 104. In alternative embodiments, this step may be implemented using the multi-chamber configuration shown in FIGS. 4A and 4B, where gas may be independently flowed into a plurality of pressure chambers 430a, 430b, and 430c to create a customized anisotropically deformation pattern.

At block 906, a second wafer may be aligned over the first wafer, the second wafer being held by a wafer carrier. This step may correspond to the configuration shown in FIGS. 2B and 3B, where the second wafer 106 may be held by the wafer carrier 108 and aligned over the first wafer 104. As described with reference to FIGS. 1A-1D, both wafers may have plasma activation prior to this alignment step to prepare their surfaces for direct bonding.

At block 908, the second wafer may be placed on the first wafer. This step may correspond to the processes shown in FIGS. 2C and 3C, where the striker 110 may apply pressure to the second wafer 106 to initiate contact with the first wafer 104, followed by the release of vacuum holding the second wafer 106 to allow bond propagation. During this step, the anisotropic deformation of the first wafer 104 may compensate for the direction-dependent stretching of the second wafer 106.

At block 910, the second wafer may be bonded to the first wafer. This step may correspond to the processes shown in FIGS. 2D and 3D, where the gas may be vacuumed out of the pressure chamber 130 to flatten the bonded wafers. As described with reference to FIGS. 7 and 8, the anisotropic deformation capabilities of the flexible wafer chuck may result in reduced residual misalignment and improved bonding yield compared to conventional approaches. Following this step, the bonded wafers may undergo additional processing such as low-temperature annealing to strengthen the bond as described earlier.

While FIG. 9 illustrates the main steps of the wafer bonding process, additional embodiment steps and processes described above with reference to FIGS. 1A-8 may be incorporated between the illustrated blocks. For example, prior to block 902, the first and second wafers may undergo plasma activation to prepare their surfaces for direct bonding as described with reference to FIG. 1A. In another example, between blocks 902 and 904, the flexible wafer chuck may be characterized to determine its deformation characteristics along different directions, similar to the analysis shown in FIGS. 5A-5C. In other example, between blocks 904 and 906, the deformation of the first wafer may be measured and verified using optical or mechanical sensors to ensure it matches the desired pattern illustrated in FIG. 6C. These additional steps, while not explicitly shown in the flow chart, may be incorporated into the overall process to enhance bonding precision and yield.

While the aspects of this disclosure are described primarily in the context of compensating for anisotropic mechanical properties in silicon wafers during bonding, it should also be appreciated that these aspects may apply to various other wafer materials exhibiting direction-dependent mechanical behavior. In particular, aspects of this disclosure may similarly apply to compound semiconductor wafers such as gallium arsenide (GaAs), gallium nitride (GaN), silicon carbide (SiC), and indium phosphide (InP), which may exhibit different crystallographic anisotropy patterns than silicon. The direction-dependent deformation techniques described herein may also benefit the bonding of other substrate materials including sapphire, glass, quartz, lithium niobate, lithium tantalate, and various composite or engineered substrates that may have inherent anisotropic properties due to their crystal structure, layered composition, or manufacturing processes. Additionally, these techniques may be valuable for heterogeneous integration where materials with significantly different mechanical properties must be precisely aligned and bonded to one another.

Example embodiments of the invention are described below. Other embodiments can also be understood from the entirety of the specification as well as the claims filed herein.

Example 1. An apparatus for wafer bonding, the apparatus including: a flexible wafer chuck configured to support a first wafer; a pressure chamber within the flexible wafer chuck; and a wall of the flexible wafer chuck separating the pressure chamber from the first wafer, the wall being configured to be anisotropically deformed when pressure is applied to the pressure chamber.

Example 2. The apparatus of example 1, further including: a gas flow line coupled to the pressure chamber and configured to flow gas into the pressure chamber; and a vacuum line coupled to the pressure chamber and configured to remove gas from the pressure chamber.

Example 3. The apparatus of one of examples 1 or 2, further including a controller coupled to the gas flow line and the vacuum line, the controller configured to: control a flow rate of gas into the pressure chamber; regulate pressure within the pressure chamber to anisotropically deform the wall; and control evacuation of a gas from the pressure chamber through the vacuum line to remove anisotropic deformation in the wall.

Example 4. The apparatus of one of examples 1 to 3, where a thickness of the wall varies based on a radial distance from a center point of the wall.

Example 5. The apparatus of one of examples 1 to 4, where a thickness of the wall varies based on an angular position relative to a center point of the wall.

Example 6. The apparatus of one of examples 1 to 5, where a material of the wall includes a mechanical property that varies based on a radial distance or an angular position relative to a center point of the wall.

Example 7. The apparatus of one of examples 1 to 6, where the flexible wafer chuck includes a polymer material including polyimide, polydimethylsiloxane (PDMS), polyether ether ketone (PEEK), fluoropolymers, polyurethane, silicone elastomers, or fluoroelastomers, or a ceramic material including silicon carbide, silicon nitride, aluminum oxide, aluminum nitride, or zirconium oxide.

Example 8. The apparatus of one of examples 1 to 7, further including a wafer carrier configured to hold a second wafer and align the second wafer to the first wafer.

Example 9. The apparatus of one of examples 1 to 8, where the wafer carrier includes a vacuum zone configured to create a vacuum between the wafer carrier and the second wafer to securely hold the second wafer.

Example 10. An apparatus for wafer bonding, the apparatus including: a flexible wafer chuck configured to hold a first wafer; a plurality of pressure chambers within the flexible wafer chuck; a plurality of gas flow lines, each gas flow line coupled to each of the plurality of pressure chambers; and a controller coupled to the plurality of gas flow lines, the controller configured to: independently control gas flow into each of the plurality of pressure chambers, independently regulate pressure within each of the plurality of pressure chambers to anisotropically deform the flexible wafer chuck to compensate for anisotropic mechanical properties of the first wafer.

Example 11. The apparatus of example 10, where the controller is further coupled to a plurality of vacuum lines, each vacuum line coupled to each of the plurality of pressure chambers.

Example 12. The apparatus of one of examples 10 or 11, where the controller is configured to independently control evacuation of gas from the plurality of pressure chambers through the plurality of vacuum lines to reduce pressures within each of the plurality of pressure chambers.

Example 13. The apparatus of one of examples 10 to 12, further including a wafer carrier configured to hold a second wafer and align the second wafer to the first wafer.

Example 14. The apparatus of one of examples 10 to 13, where the flexible wafer chuck includes a polymer material including polyimide, polydimethylsiloxane (PDMS), polyether ether ketone (PEEK), fluoropolymers, polyurethane, silicone elastomers, or fluoroelastomers, or a ceramic material including silicon carbide, silicon nitride, aluminum oxide, aluminum nitride, or zirconium oxide.

Example 15. The apparatus of one of examples 10 to 14, where the plurality of pressure chambers includes a first pressure chamber including a first volume and a second pressure chamber including a second volume, where the first volume is different from the second volume.

Example 16. A method for wafer bonding, the method including: placing a first wafer over a flexible wafer chuck, the flexible wafer chuck including a pressure chamber, where a wall of the flexible wafer chuck separates the pressure chamber from the first wafer; flowing a gas into the pressure chamber to apply a pressure to the wall of the pressure chamber to anisotropically deform the first wafer to compensate for anisotropic mechanical properties of the first wafer; placing a second wafer on the first wafer; and bonding the second wafer to the first wafer.

Example 17. The method of example 16, where placing the second wafer includes: aligning the second wafer over the first wafer, the second wafer being held by a wafer carrier; applying pressure to the second wafer using a striker to place the second wafer on the first wafer; and releasing vacuum holding the second wafer as bond propagation occurs, allowing the second wafer to stretch and temporarily bond with the first wafer.

Example 18. The method of one of examples 16 or 17, where the bonding includes vacuuming the gas out of the pressure chamber to remove anisotropic deformation in the first wafer.

Example 19. The method of one of examples 16 to 18, where the bonding includes a direct bonding process that forms a hybrid bond between the first wafer and the second wafer.

Example 20. The method of one of examples 16 to 19, where flowing the gas into the pressure chamber includes adjusting a height of deformation of the flexible wafer chuck to reduce residual misalignment between the first and the second wafers.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. For example, the embodiments illustrated and described using FIGS. 1A-9 may be combined in further embodiments. It is therefore intended that the appended claims encompass any such modifications or embodiments.

What is claimed is:

1. An apparatus for wafer bonding, the apparatus comprising:
a flexible wafer chuck configured to support a first wafer;
a pressure chamber within the flexible wafer chuck; and
a wall of the flexible wafer chuck separating the pressure chamber from the first wafer, the wall being configured to be anisotropically deformed when pressure is applied to the pressure chamber.

2. The apparatus of claim 1, further comprising:
a gas flow line coupled to the pressure chamber and configured to flow gas into the pressure chamber; and
a vacuum line coupled to the pressure chamber and configured to remove gas from the pressure chamber.

3. The apparatus of claim 2, further comprising a controller coupled to the gas flow line and the vacuum line, the controller configured to:
control a flow rate of gas into the pressure chamber;
regulate pressure within the pressure chamber to anisotropically deform the wall; and
control evacuation of a gas from the pressure chamber through the vacuum line to remove anisotropic deformation in the wall.

4. The apparatus of claim 1, wherein a thickness of the wall varies based on a radial distance from a center point of the wall.

5. The apparatus of claim 1, wherein a thickness of the wall varies based on an angular position relative to a center point of the wall.

6. The apparatus of claim 1, wherein a material of the wall comprises a mechanical property that varies based on a radial distance or an angular position relative to a center point of the wall.

7. The apparatus of claim 1, wherein the flexible wafer chuck comprises a polymer material comprising polyimide, polydimethylsiloxane (PDMS), polyether ether ketone (PEEK), fluoropolymers, polyurethane, silicone elastomers, or fluoroelastomers, or a ceramic material comprising silicon carbide, silicon nitride, aluminum oxide, aluminum nitride, or zirconium oxide.

8. The apparatus of claim 1, further comprising a wafer carrier configured to hold a second wafer and align the second wafer to the first wafer.

9. The apparatus of claim 8, wherein the wafer carrier comprises a vacuum zone configured to create a vacuum between the wafer carrier and the second wafer to securely hold the second wafer.

10. An apparatus for wafer bonding, the apparatus comprising:
a flexible wafer chuck configured to hold a first wafer;
a plurality of pressure chambers within the flexible wafer chuck;
a plurality of gas flow lines, each gas flow line coupled to each of the plurality of pressure chambers; and
a controller coupled to the plurality of gas flow lines, the controller configured to:
independently control gas flow into each of the plurality of pressure chambers,
independently regulate pressure within each of the plurality of pressure chambers to anisotropically deform the flexible wafer chuck to compensate for anisotropic mechanical properties of the first wafer.

11. The apparatus of claim 10, wherein the controller is further coupled to a plurality of vacuum lines, each vacuum line coupled to each of the plurality of pressure chambers.

12. The apparatus of claim 11, wherein the controller is configured to independently control evacuation of gas from the plurality of pressure chambers through the plurality of vacuum lines to reduce pressures within each of the plurality of pressure chambers.

13. The apparatus of claim 10, further comprising a wafer carrier configured to hold a second wafer and align the second wafer to the first wafer.

14. The apparatus of claim 10, wherein the flexible wafer chuck comprises a polymer material comprising polyimide, polydimethylsiloxane (PDMS), polyether ether ketone (PEEK), fluoropolymers, polyurethane, silicone elastomers, or fluoroelastomers, or a ceramic material comprising silicon carbide, silicon nitride, aluminum oxide, aluminum nitride, or zirconium oxide.

15. The apparatus of claim 10, wherein the plurality of pressure chambers comprises a first pressure chamber comprising a first volume and a second pressure chamber comprising a second volume, wherein the first volume is different from the second volume.

16. A method for wafer bonding, the method comprising:
placing a first wafer over a flexible wafer chuck, the flexible wafer chuck comprising a pressure chamber, wherein a wall of the flexible wafer chuck separates the pressure chamber from the first wafer;
flowing a gas into the pressure chamber to apply a pressure to the wall of the pressure chamber to anisotropically deform the first wafer to compensate for anisotropic mechanical properties of the first wafer;
placing a second wafer on the first wafer; and
bonding the second wafer to the first wafer.

17. The method of claim 16, wherein placing the second wafer comprises:
aligning the second wafer over the first wafer, the second wafer being held by a wafer carrier;
applying pressure to the second wafer using a striker to place the second wafer on the first wafer; and
releasing vacuum holding the second wafer as bond propagation occurs, allowing the second wafer to stretch and temporarily bond with the first wafer.

18. The method of claim 16, wherein the bonding comprises vacuuming the gas out of the pressure chamber to remove anisotropic deformation in the first wafer.

19. The method of claim 16, wherein the bonding comprises a direct bonding process that forms a hybrid bond between the first wafer and the second wafer.

20. The method of claim 16, wherein flowing the gas into the pressure chamber comprises adjusting a height of deformation of the flexible wafer chuck to reduce residual misalignment between the first and the second wafers.
